(19) United States
(12) Patent Application Publication
(10) Pub. No.: US 2026/0113003 A1
(43) Pub. Date: Apr. 23, 2026

(54) AUDIO CROSSTALK REDUCTION

(71) Applicant: TEXAS INSTRUMENTS INCORPORATED, Dallas, TX (US)

(72) Inventors: Jyoti Raj, New Delhi (IN); Syed Hameed, Hyderabad (IN); Anand Subramanian, Dallas, TX (US)

(21) Appl. No.: 19/217,864

(22) Filed: May 23, 2025

(30) Foreign Application Priority Data
Oct. 23, 2024 (IN) 202441080778

(51) Int. Cl. H03F 3/183; H03F 1/52; H04R 3/00

(52) U.S. Cl. CPC H03F 3/183; H03F 1/52; H04R 3/007; H03F 2200/03; H03F 2200/372

(57) ABSTRACT

An apparatus includes a first switch having a first switch terminal coupled to a first terminal and having a second switch terminal. A second switch has a third switch terminal coupled to a second terminal and has a fourth switch terminal. A first amplifier has a first input and a second input. A second amplifier has a third input and has a first output. A common mode generation circuit has first and second terminals. The first terminal of the common mode generation circuit is coupled to the second switch terminal and to the fourth switch terminal, and the second terminal of the common mode generation circuit is coupled to the first amplifier and to the third input.

### CROSS-REFERENCE TO RELATED APPLICATIONS

This application claims priority to India Provisional Application No. 202441080778, filed Oct. 23, 2024, which is hereby incorporated by reference.

### TECHNICAL FIELD

The present disclosure relates generally to an electronic system and method, and, in particular embodiments, to audio crosstalk reduction.

### BACKGROUND

An audio headset may include one or more speakers (e.g., a left speaker and a right speaker) and a microphone. The headset may have a cable to which the speakers and microphone are connected. The speakers and microphone share a ground. The distal end of the cable may include an audio jack which may be inserted into a connector on an electronic system. Examples of an electronic system include a personal computer, tablet device, smart phone. The electronic system may include a printed circuit board (PCB) on which the system's components are mounted. One of such components includes an audio integrated circuit (IC), which is coupled via, for example, traces on the PCB to the connector.

### SUMMARY

In one example, an apparatus includes a first switch having a first switch terminal coupled to a first terminal and having a second switch terminal. A second switch has a third switch terminal coupled to a second terminal and has a fourth switch terminal. A first amplifier has a first input and a second input. A second amplifier has a third input and has a first output. A common mode generation circuit has first and second terminals. The first terminal of the common mode generation circuit is coupled to the second switch terminal and to the fourth switch terminal, and the second terminal of the common mode generation circuit is coupled to the first amplifier and to the third input.

In another example, an integrated circuit (IC) includes an audio amplifier having first and second inputs coupled to respective first and second terminals of the IC. A microphone bias amplifier has a third input and has a first output. The first output is coupled to at least one of a third terminal and a fourth terminal of the IC. A common mode generation circuit has a second output coupled to the audio amplifier and to the microphone bias amplifier. The common mode generation circuit is configured to provide a common mode voltage for the audio amplifier and the microphone bias amplifier. The common mode generation circuit has a first ground coupled to at least one of a fifth terminal and a sixth terminal of the IC.

In yet another example, a system includes an audio connector and includes an audio amplifier having inputs coupled to the audio connector. A microphone bias amplifier has an input and a first output. The first output is coupled through to the audio connector. A common mode generation circuit has a second output coupled to at least one input of the audio amplifier and to the input of the microphone bias amplifier. The common mode generation circuit has a common mode generation circuit ground coupled to the audio connector.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a system diagram illustrating a headset connected to an electronic system, in accordance with an embodiment of the disclosure;

FIGS. 2 and 3 are examples of audio jacks coupled to the headset of FIG. 1 in accordance with embodiments of the disclosure;

FIG. 4 is a schematic diagram of an integrated circuit which includes a microphone interface circuit, in accordance with an embodiment of the disclosure;

FIGS. 5A and 5B (collectively, FIG. 5) include a schematic diagram of an integrated circuit which includes a microphone interface circuit, in accordance with an embodiment of the disclosure; and

FIG. 6 is a schematic diagram illustrating an embodiment of ground switch circuits.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

In some audio applications, the traces between an audio connector and the audio IC have parasitic resistance. Because of such parasitic resistance, crosstalk may be present on the common ground shared between the speakers and the microphone. Due to such crosstalk, the common ground may have a reduced magnitude version of the audio signals provided to the speakers. In some audio applications, the crosstalk caused by the parasitic resistance along with the on-resistance of an internal ground switch may result in the audio IC receiving a signal from the microphone that includes crosstalk from the speakers.

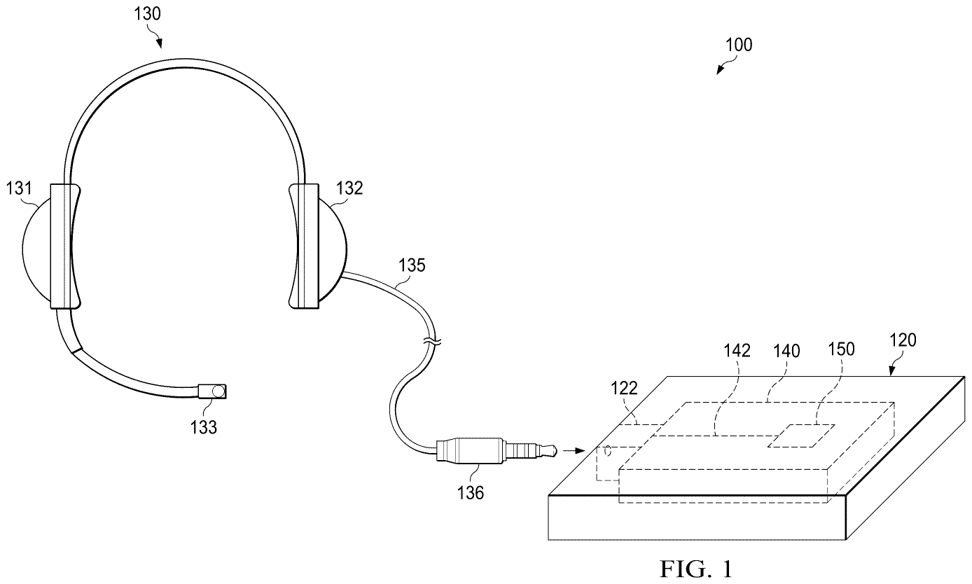

FIG. 1 is a system diagram illustrating a headset 130 connected to an electronic system 120, according to an embodiment of the present disclosure. Electronic system 120 may be a personal computer, a tablet device, a smartphone, etc. Headset 130 has a left speaker 131, a right speaker 132, and a microphone 133. Headset 130 has, or is coupled to, a cable 135. Cable 135 has an audio jack 136 which may plug into a corresponding connector 122 on electronic system 120. Electronic system 120 has a circuit board 140 on which one or more components are mounted. Integrated circuit (IC) 150 is mounted on circuit board 140. IC 150 includes an audio circuit to interface with speakers 131, 132 and microphone 133.

In an embodiment, the audio circuit may receive and amplify an audio signal to be provided to either or both speakers 131 and 132 as well as receive a microphone signal from microphone 133. The audio circuit may amplify and/or process the microphone signal. One or more traces 142 on circuit 140 couple connector 122 to IC 150. Traces 142 have a parasitic resistance which can vary from application to application depending on the length of the traces between connector 122 and IC 150, the width of the traces 142, etc.

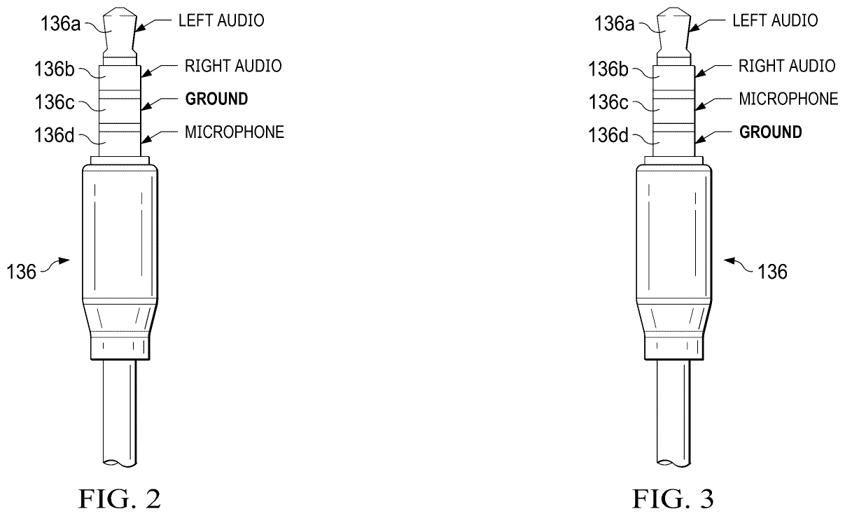

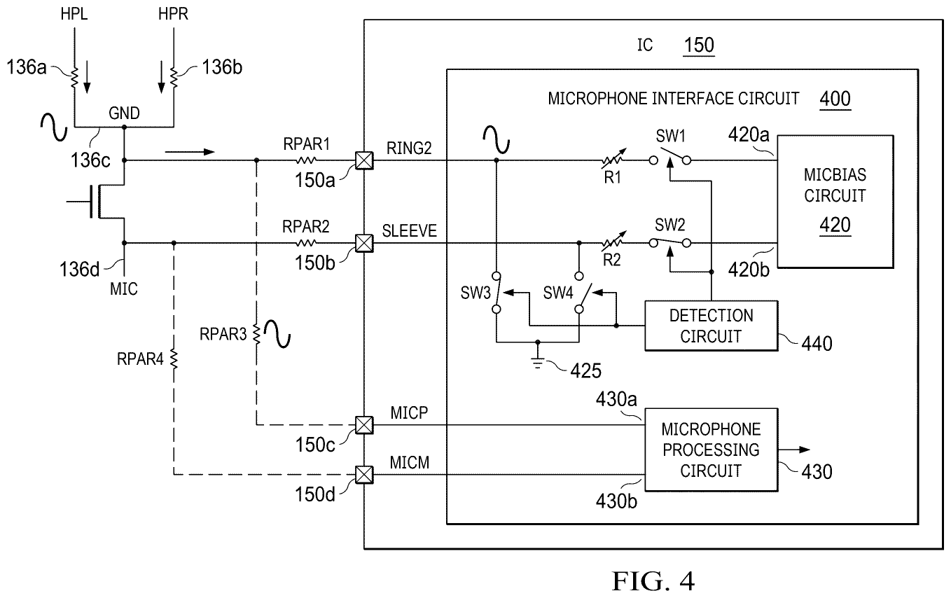

FIGS. 2 and 3 are depictions of two different standards for audio jack 136. The audio jacks in FIGS. 2 and 3 are physically the same size and have the same number of contacts. Each audio jack in FIGS. 2 and 3 has contacts 136a, 136b, 136c, and 136d. Contacts 136a, 136b, 136c, and 136d may be referred to as the TIP, RING1, RING2, and SLEEVE contacts, respectively. Contacts 136a and 136b in both figures are coupled to the left speaker 131 and right speaker 132, respectively. The difference between the audio jack examples in FIGS. 2 and 3 is the configuration of the contacts coupled to the common ground and microphone 133. In the example of FIG. 2, contacts 136c and 136d are coupled to the ground and microphone 133, respectively, while in the example of FIG. 3, contacts 136c and 136d are coupled to the microphone 133 and ground, respectively. Audio jack 136 in FIG. 2 may represent the Cellular Telecommunications Industry Association (CTIA) standard. Audio jack 136 in FIG. 3 may represent the Open Mobile Terminal Platform (OMTP) standard.

Because either audio jack 136 in FIG. 2 or 3 can be physically connected to connector 122, electronic system 120 includes a detection circuit (e.g., as part of IC 150) to detect which version of the audio jack 136 is connected to the connector 122. The detected ground contact is coupled to ground within IC 150, and the detected microphone contact is connected to a microphone bias voltage.

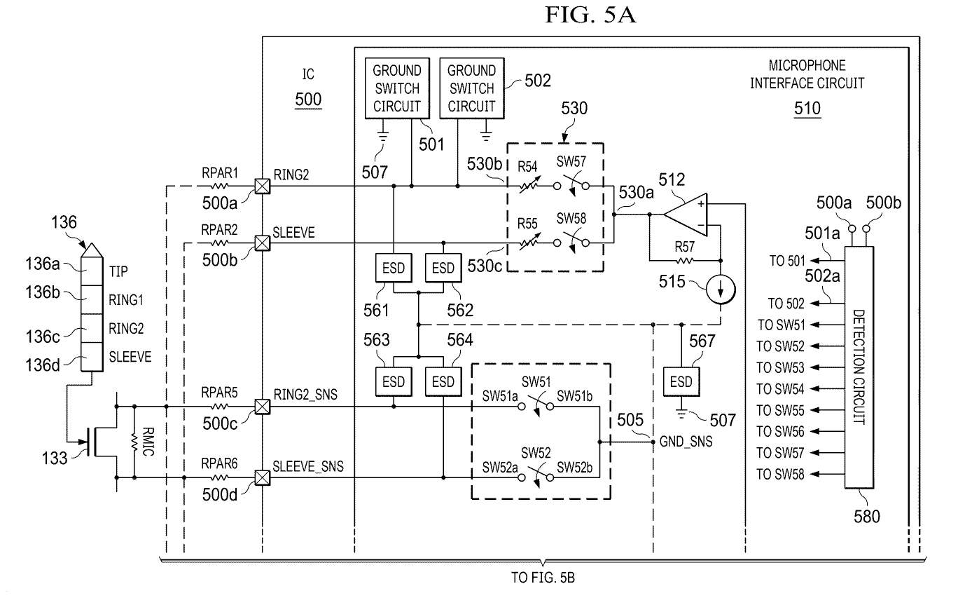

FIG. 4 is a schematic diagram of IC 150, according to an embodiment of the present disclosure. IC 150 includes a microphone interface circuit 400. Additional circuitry (not shown) may be included as part of IC 150, e.g., to provide audio signals to the left speaker 131 and right speaker 132.

In some embodiments, microphone interface circuit 400 includes a microphone bias (MICBIAS) circuit 420, a microphone processing circuit 430, a detection circuit 440, switches SW1, SW2, SW3, and SW4 (e.g., transistors), and resistors R1 and R2. Microphone processing circuit 430 may include an amplifier and an analog-to-digital converter (ADC) to amplify a signal from microphone 133 and convert the microphone's signal to digital values. IC 150 includes terminals 150a (RING2), 150b (SLEEVE), 150c (MICP), and 150d (MICM). Terminals 150a and 150c are coupled to contact 136c within audio jack 136, and terminals 150b and 150d are coupled to contact 136d within audio jack 136. Resistor R1 and switch SW1 are coupled in series between a terminal 420a of microphone bias circuit 420 and terminal 150a. Similarly, resistor R2 and switch SW2 are coupled in series between a terminal 420b of microphone bias circuit 420 and terminal 150b. Switch SW3 is coupled between terminal 150a and ground 425, which is a ground within IC 150. Switch SW4 is coupled between terminal 150b and ground 425. Microphone interface circuit 430 has terminals 430a and 430b which are coupled to terminals 150c and 150d, respectively. Detection circuit 440 generates control signals which can control the open and closed state of switches SW1-SW4.

In some embodiments, detection circuit 440 determines whether contact 136c is ground or whether contact 136d is ground. In one embodiment, detection circuit 440 may measure the resistance between contact 136a (or 136b) and contact 136c. The measured resistance will be the resistance (e.g., 8 ohms to 600 ohms) of the left (or right) speaker within the headset 130 if contact 136c is ground. Otherwise, if contact 136c is the microphone contact and contact 136d is ground, then the measured resistance between contacts 136a and 136c will be substantially higher than the resistance of the left (or right) speaker.

FIG. 4 illustrates the scenario in which detection circuit 440 has determined that contact 136c is ground and contact 136d is coupled to the microphone. In response to this determination, detection circuit 440 causes switches SW2 and SW3 to be closed and switches SW1 and SW4 to be open (as shown in FIG. 4).

Microphone 133 in headset 130 should be biased with a suitable bias voltage (e.g., 2.5V). In some embodiments, microphone bias circuit 420 provides the bias voltage through resistor R2. Because contact 136c is determined to be the headset's common ground, switch SW3 is closed by detection circuit 440 to couple contact 136c to the IC's ground 425.

Resistance RPAR1 represents the parasitic resistance between contact 136c and terminal 150a. Resistance RPAR2 represents the parasitic resistance between contact 136d and terminal 150b. Resistance RPAR3 represents the parasitic resistance between contact 136c and terminal 150c. Resistance RPAR4 represents the parasitic resistance between contact 136d and terminal 150d. Parasitic resistances RPAR1-RPAR4 may include the resistance of traces on circuit board 140 coupling contacts 136c/136d to the corresponding terminals 150a-150d of IC 150. When closed, switches SW3 and SW4 also have parasitic resistance. In one embodiment, switches SW3 and SW4 can be implemented as transistors whose parasitic resistance is the on-resistance of the transistor.

The audio signal provided to the left and/or right headset speaker is generated within electronic system 100 (e.g., by IC 150). The ground reference for that audio signal may be ground 425 within IC 150. The audio signal is applied to contact 136a and/or contact 136b within audio jack 136. Between contact 136a and ground 425, a voltage divider includes the series combination of the resistance of the left speaker, RPAR1, and the parasitic resistance of switch SW3. Accordingly, a reduced amplitude version of the audio signal, referred to as a crosstalk audio signal, is present across parasitic resistance RPAR1. Because the actual ground for the audio signal provided to the speakers in the headset is the ground 425 of IC 150, contact 136c has a reduced amplitude version of the audio signal (crosstalk audio signal) and this reduced headphone audio signal may be comparable in magnitude to the microphone signal which will act as the full scale signal for the processing circuit 430. Further, because contact 136c (or 136d) is a ground contact shared by the microphone and coupled to microphone interface circuit 430, microphone interface circuit 430 may receive crosstalk audio from headset speakers. Some embodiments advantageously reduces such crosstalk.

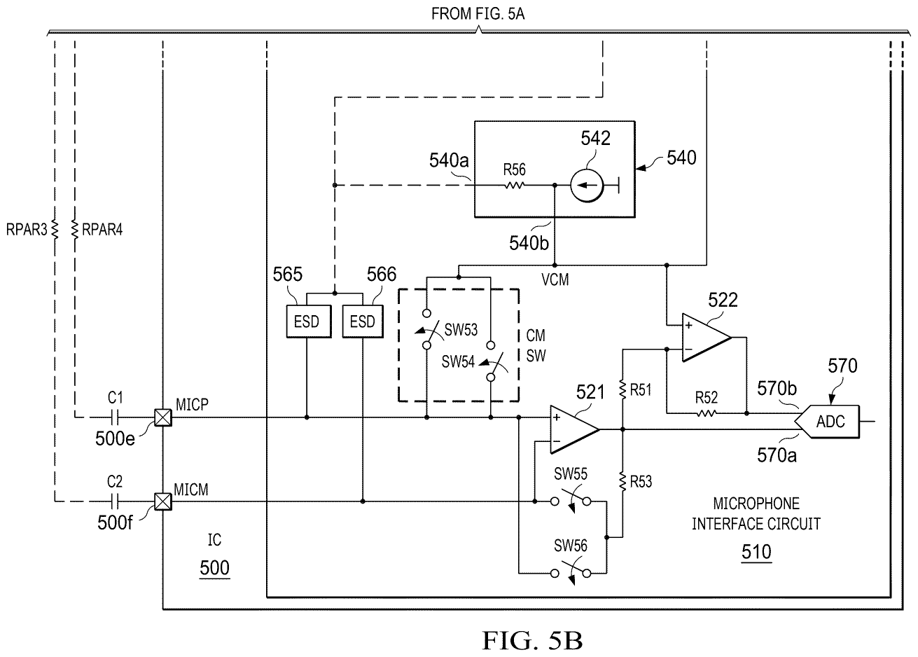

For example, FIG. 5 is a schematic diagram of a microphone interface circuit 510 fabricated on an IC 500, according to an embodiment of the present disclosure. Other circuits, such as circuits that provide audio signals to the left and right speakers 131, 132 in headset 130 may also be provided on IC 500.

In some embodiments, microphone interface circuit 400 may be implemented as microphone interface circuit 510. For example, in some embodiments, MICBIAS circuit 420 may include amplifier 512, detection circuit 440 may be implemented as detection circuit 580, microphone processing circuit 430 may include microphone interface circuit 510, switches SW1 and SW2 may be implemented as switches SW57 and SW58, respectively, and switches SW3 and SW4 may be implemented as ground switch circuits 501 and 502, respectively.

As shown in FIG. 5, microphone interface circuit 510 includes ground switch circuits 501 and 502, amplifiers 512, 521, and 522, a bias resistor circuit 530, a common mode generation circuit 540, an ADC 570, switches SW51, SW52, SW53, SW54, SW55, and SW56 (e.g., transistors), electrostatic discharge (ESD) circuits 561, 562, 563, 564, 565, 566, and 567, and a detection circuit 580. Each switch SW51-SW56 has a pair of terminals through which current can flow and a control terminal.

In an embodiment in which the switches are field effect transistors (FETs), the pair of terminals through which current flows are the drain and source, and the control terminal is the gate. Switch SW51 has switch terminals SW51a and SW51b. Switch SW52 has switch terminals SW52a and SW52b. IC 500 has terminals 500a, 500b, 500c, 500d, 500e, and 500f. When audio jack 136 is coupled to connector 122 on electronic system 120, contact 136c of the audio jack is coupled to terminals 500a, 500c, and 500f, and contact 136d is coupled to terminals 500b, 500d, and 500e. Parasitic resistances RPAR1, RPAR5, and RPAR3 represent PCB parasitic resistances between contact 136c and terminals 500a, 500c, and 500f, respectively. Parasitic resistances RPAR2, RPAR6, and RPAR4 represent PCB parasitic resistances between contact 136d and terminals 500b, 500d, and 500e, respectively. Switch terminal SW51a is coupled to terminal 500c, and switch terminal SW52a is coupled to terminal 500d. Switch terminals SW51b and SW52b are coupled together at a ground sense (GND_SNS) terminal 505 within IC 500.

In some embodiments, detection circuit 580 determines which of contacts 136c or 136d is the common ground for the audio jack 136 based on, for example, resistance measurements between contacts of the audio jack as described above. Based on the determination as to which contact 136c, 136d is the audio jack ground, detection circuit 580 configures switches SW51-SW58 and ground circuits 501 and 502, as described below. The control signals to ground switch circuits 501 and 502 are control signals 501a and 502a, respectively.

In some embodiments, common mode generation circuit 540 generates a common mode voltage (VCM) for at least some of the circuits within microphone interface circuit 510. In the embodiment of FIG. 5, common mode generation circuit 540 includes a current source 542 coupled to a resistor R56. One terminal of resistor R56 is coupled to current source 542 and to an output 540b of common mode generation circuit 540. The other terminal of resistor R56 is coupled to the ground reference 540a of common mode generation circuit 540. As described below, ground reference 540a may be at a different voltage than ground 507 of IC 500. Common mode generation ground reference 540a is coupled to the ground sense terminal 505.

Amplifier 521 has a positive (+) input and a negative (−) input. Either input can function as the positive input or as the negative input. Switch SW53 is coupled between output 540b of common mode generation circuit 540 and the positive input of amplifier 521, and switch SW54 is coupled between output 540b of common mode generation circuit 540 and the negative input of amplifier 521. In one embodiment, amplifier 521 is a low noise preamplifier to amplify the signal from microphone 133 received at terminals 500e and 500f through capacitors C1 and C2. Capacitors C1 and C2 function, at least in part, as alternating current (AC)-coupling capacitors thereby blocking DC bias voltage from microphone 133 from reaching the positive and/or negative inputs of amplifier 521. Resistor R53 is coupled between the output of amplifier 521 and terminals of switches SW55 and SW56. If switch SW53 is closed to provide VCM to the input marked as positive of amplifier 521, switch SW55 is closed to couple resistor R53 to the other input (which is the negative input of amplifier 521). The polarity of the inputs of amplifier 521 can be reversed from that shown. Whichever input receives the VCM voltage, the other input is coupled to resistor R53.

The other terminals of switches SW55 and SW57 are coupled to the negative and positive inputs, respectively, of amplifier 521. Amplifier 522 also has a positive input and a negative input. The output 540b of common mode generation circuit 540 is coupled to the positive input of amplifier 522. One terminal of resistor R51 is coupled to the output of amplifier 521, and the other terminal of resistor R51 is coupled to the negative input of amplifier 522. One terminal of resistor R52 is also coupled to the negative input of amplifier 522, and the other terminal of resistor R52 is coupled to the output of amplifier 522.

In some embodiments, amplifier 522 is configured as an inverting amplifier to invert the output signal from amplifier 521 so as to convert single-ended microphone signals into differential signals. The outputs of amplifiers 521 and 522 are coupled to differential inputs 570a and 570b, respectively, of ADC 570.

In some embodiments, ADC 570 converts the amplified differential signal to a digital value at its output. The output of ADC 570 may be coupled to a processor or other type of logic, for example, for processing, storage, etc.

In some embodiments, amplifier 512 is operative to provide a bias voltage to microphone 133. Amplifier 512 has a positive input, a negative input, and an output. The positive input is coupled to the output 540b of common mode generation circuit 540, thereby allowing common mode generation circuit 540 to generate the common mode voltage VCM for amplifiers 512, 521, and 522. Resistor R57 is coupled between the output of amplifier 512 and the negative input. The negative input is coupled to the ground sense terminal 505. Current source 515 provides a DC bias current for amplifier 512 and is coupled between the negative input of amplifier 512 and the ground sense terminal 505. Amplifier 512 amplifies the common mode voltage VCM to a level suitable for biasing microphone 133 (e.g., between 1.7V and 2.8V).

Bias resistor circuit 530 has terminals 530a, 530b, and 530c. Terminal 530a is coupled to the output of amplifier 512. Bias resistor circuit 530 includes resistors R54 and R55 and switches SW57 and SW58. Resistor R54 and switch SW57 are coupled in series between terminals 530a and 530b. Resistor R55 and switch SW58 are coupled in series between terminals 530a and 530c. Terminal 530b is coupled to terminal 500a of IC 500, and terminal 530c is coupled to terminal 500b of IC 500.

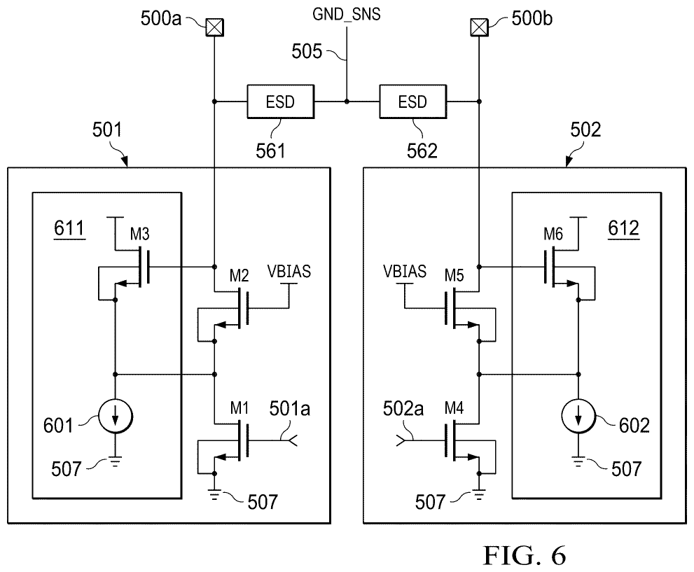

Ground switch circuit 501 is coupled to terminal 500a. Ground switch circuit 502 is coupled to terminal 500b. When ground switch circuit 501 is enabled, terminal 500a is coupled to ground 507. Similarly, when ground switch circuit 502 is enabled, terminal 500b is coupled to ground 507. In some embodiments, one, but not both, of ground switch circuits 501 and 502 is enabled based on whether contact 136c or 136d is determined by detection circuit 580 to be the common ground for audio jack 136. Upon determining which of contacts 136c and 136d is the audio jack's ground, detection circuit 580 enables the corresponding ground switch circuit 501, 502. For example, if detection circuit 580 determines that contact 136c is the audio jack's ground, detection circuit 580 enables ground switch 501 and disables ground switch circuit 502. Similarly, if detection circuit 580 determines that contact 136d is the audio jack's ground, detection circuit 580 enables ground switch 502 and disables ground switch circuit 501. Ground switch circuits 501 and 502 are further described below with reference to FIG. 6.

As described above, based on which of contacts 136c and 136d is the audio jack's ground, detection circuit 580 controls switches SW51-SW58 and ground switch circuits 501 and 502. For example, responsive to determining that contact 136c is the audio jack ground, detection circuit 580 enables ground switch circuit 501, disables ground switch 502, closes switches SW51, SW54, SW56, and SW58, and opens switches SW52, SW53, SW55, and SW57. By enabling ground switch circuit 501, terminal 500a is coupled to ground 507 within IC 500. With switch SW51 closed, the ground sense terminal 505 may carry a crosstalk audio signal resulting from, for example, parasitic resistance RPAR5, as described above. With the ground sense terminal 505 carrying the crosstalk audio signal, the ground reference, the common mode voltage VCM has two components. A first component is a DC voltage generated by current from current source 542 flowing through resistor R56 thereby generating a DC voltage at output 540b which amplifiers 521, 522 and 512 use as a common mode voltage common to all three amplifiers). A second component is a crosstalk audio signal superimposed on the DC voltage at output 540b as a result of the ground reference of common mode generation circuit 540 carrying the crosstalk audio signal. In other words, common mode voltage VCM is referenced with respect to the ground sense terminal 505 and, accordingly, is a DC voltage on which the crosstalk audio signal is superimposed.

Common mode voltage VCM provides a bias voltage to amplifier 521 through switch SW54 (which is closed if contact 136c is the audio jack's ground). Common mode voltage VCM is also provided to the positive inputs of amplifiers 522 and 512. Accordingly, the crosstalk audio signal (superimposed on a DC voltage) is also present on the positive inputs of amplifiers 522 and 512. Because of the virtual ground between the positive and negative inputs of amplifier 512, the crosstalk audio signal is also present on the negative input of amplifier 512. Further, because ground sense terminal 505 is coupled to current source 515, little or no audio signal current flows through resistor R57 and, accordingly, the output of amplifier 512 also carries the crosstalk audio signal superimposed on the DC voltage generated by amplifier 512. Amplifier 512 provides sufficient amplification to generate an output bias voltage for biasing microphone 133 (e.g., between 1.7V and 2.8V)

With switch SW58 closed (which is closed responsive to contact 136c being determined to be the audio jack's ground), the output voltage from amplifier 512 is provided to terminal 500b, which is coupled through contact 136d to microphone 133. Accordingly, the bias voltage for microphone 133 is a DC voltage on which the crosstalk audio signal is superimposed. Both connections to the microphone carry the crosstalk audio signal—the ground carries the crosstalk audio signal due to board parasitic resistances as described above, and the microphone's active terminal (contact 13d in this embodiment) also carries the crosstalk audio signal. Because contact 136c is coupled through terminal 500f to the negative input of amplifier 521, the negative input of amplifier 521 carries the crosstalk audio signal. With both the positive and negative inputs of amplifier 521 carrying the crosstalk audio signal, the output signal from amplifier 512 also carries the crosstalk audio signal. Further, both the positive and negative inputs of amplifier 522 carry the same crosstalk audio signal, and thus the output signals from amplifiers 522 and 521 carry the crosstalk audio signal. The differential inputs 570a and 570b of ADC 570 have the same common crosstalk audio signal. Because ADC 570 has a differential input, and the differential input has the same crosstalk audio signal, ADC 570 digitizes the microphone's output signal while advantageously cancelling the crosstalk audio signal.

The same result occurs if contact 136d is determined by detection circuit 580 to be the audio jack's ground. In this case, responsive to determining that contact 136d is the audio jack ground, detection circuit 580 enables ground switch circuit 502, disables ground switch 501, closes switches SW52, SW53, SW55, and SW57, and opens switches SW51, SW54, SW56, and SW58. By enabling ground switch circuit 502, terminal 500b is coupled to ground 507 within IC 500. With switch SW52 closed, the ground sense terminal 505 may carry the crosstalk audio signal resulting from, for example, parasitic resistance RPAR6. As described above, the common mode voltage VCM includes a DC voltage on which the crosstalk audio signal is superimposed.

Common mode voltage VCM provides the bias voltage to amplifier 521 through switch SW53 (which is closed if contact 136d is the audio jack's ground). Common mode voltage VCM is also provided to the positive inputs of amplifiers 522 and 512, as noted above. With switch SW57 closed (which is closed responsive to contact 136d being determined to be the audio jack's ground), the output voltage from amplifier 512 is provided to terminal 500a, which is coupled through contact 136c to microphone 133. As described above, both connections to the microphone carry the crosstalk audio signal. Because contact 136d is coupled through terminal 500e to the positive input of amplifier 521, the positive input of amplifier 521 carries the crosstalk audio signal, as is the case for the negative input of amplifier 521. Further, both outputs of amplifiers 521 and 522 carry the same crosstalk audio signal. As described above, ADC 570 digitizes the microphone's output signal while advantageously cancelling the crosstalk audio signal.

In some embodiments, ESD circuit 561 is coupled between terminal 500a and ground sense terminal 505. ESD circuit 562 is coupled between terminal 500b and ground sense terminal 505. ESD circuit 563 is coupled between terminal 500c and ground sense terminal 505. ESD circuit 564 is coupled between terminal 500d and ground sense terminal 505. ESD circuit 565 is coupled between terminal 500e and ground sense terminal 505. ESD circuit 566 is coupled between terminal 500f and ground sense terminal 505. ESD circuit 567 is coupled between ground sense terminal 505 and ground 507 of IC 500.

To help replicate the crosstalk audio signal on the contact 136c/136d coupled to microphone 133, the impedance between contact 136c/136d and ground 507 should be larger rather than smaller to reduce any additional loading on the microphone. Each ESD circuit 561-566 may include one or more transistors (e.g., field effect transistors) and thus have a parasitic capacitance when the transistors are off. ESD circuits 561, 563, and 566 are coupled in parallel between their respective terminals 500a, 500c, and 500f and ground sense terminal 505. Parasitic capacitances in parallel add together thereby representing a larger capacitance, which may thus represent a smaller impedance in the audio frequency range. If ESD circuits 561, 563, and 566 were instead connected to ground 507 of IC 500, the loading on the microphone would be larger than is the case of the embodiment of FIG. 5 in which ESD circuits 561, 563, and 566 are coupled to ground sense terminal 505. The same is true for ESD circuits 562, 564, and 565, which are coupled in parallel between contact 136d and ground sense terminal 505, rather than to ground 505. Accordingly, a technical advantage of the embodiment of FIG. 5 in which ESD circuits 561-566 are coupled between their respective terminals 500a-500f and ground sense terminal 505 (instead of to ground 505) is that less loading results on the microphone 133, which otherwise may have caused high crosstalk as described above.

FIG. 6 is a schematic diagram illustrating an embodiment of ground switch circuits 501 and 502, according to an embodiment of the present disclosure. Ground switch circuit 501 includes transistors M1, M2, and M3 (e.g., n-channel field effect transistors, NFETs) and a current source 601. The drain of transistor M2 is coupled to terminal 500a and to the gate of transistor M3. The source of transistor M2 is coupled to the source of transistor M3 and to the drain of transistor M1, and the source of transistor M1 is coupled to ground 507. Current source 601 is coupled between the source of transistor M3 and ground 507 and provides a bias current for transistor M3. The combination of transistor M3 and current source 601 is a buffer 611. The gate of transistor M2 receives a bias voltage, VBIAS (e.g., 1.8V), to provide a gate-to-source voltage (Vgs) for transistor M2 that is at least equal to its threshold voltage of transistor M2. Transistor M2 is a cascode transistor for transistor M1 thereby permitting the use of a relatively low voltage transistors (e.g., gate-to-source voltage (Vgs) or drain-to-source voltage (Vds) equal to 1.8V).

The gate of transistor M1 receives control signal 501a from detection circuit 580. When control signal 501a from detection circuit 580 is logic high, transistor M1 turns on and ground switch circuit 501 is enabled. With both transistors M1 and M2 on, terminal 500a is coupled through transistors M1 and M2 to ground 507. With the use of low voltage transistors M1 and M2, the combined drain-to-source resistance (Rdson) of transistors M1 and M2 advantageously can be relatively small (e.g., equal to or less than 200 mohms). A single larger size transistor having a small Rdson could be used in place of transistors M1 and M2, but such a transistor would likely be disadvantageously larger than the combined sizes of transistors M1 and M2.

In some embodiments, to disable ground switch circuit 501, detection circuit 580 forces control signal 501a to a logic low state to turn off transistor M1. Without buffer 611, transistors M1 and M2, which are off when ground switch circuit 501 is disabled, have drain-to-source parasitic capacitance and drain-to-gate parasitic capacitance, which may represent an impedance within the audio frequency range such that current may flow through the disabled ground switch circuit 501 to ground 507. Buffer 611 helps to reduce loading on terminal 500a when ground switch circuit 501 is off. As described above, reducing loading on terminal 500a is advantageous to help faithfully replicate the crosstalk audio signal on the microphone signal to amplifier 521. Any crosstalk audio signal on terminal 500a when ground switch circuit 501 is off is on the gate of transistor M3 and accordingly on the sources of transistor M2 and M3, as well as, as described above, ground sense terminal 505. As a result, little, if any, loading is placed on terminal 500a when ground switch circuit 501 is disabled due to buffer 611.

Ground switch circuit 502 includes transistors M4, M5, and M6 (e.g., n-channel field effect transistors, NFETs) and a current source 602. The drain of transistor M5 is coupled to terminal 500b and to the gate of transistor M6. The source of transistor M5 is coupled to the source of transistor M6 and to the drain of transistor M4, and the source of transistor M4 is coupled to ground 507. Current source 602 is coupled between the source of transistor M6 and ground 507 and provides a bias current for transistor M6. The combination of transistor M6 and current source 602 is a buffer 612. The gate of transistor M5 receives bias voltage, VBIAS, to provide a Vgs for transistor M5 that is at least equal to its threshold voltage of transistor M5. Transistor M5 is a cascode transistor for transistor M4 thereby permitting the use of a relatively low voltage transistors. The combination of transistors M4 and M5 provides a relatively small Rdson, as described above. Further, buffer 612 helps to reduce loading on terminal 500b when ground switch circuit 502 is off.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein may be reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated.

Example embodiments of the present disclosure are summarized here. Other embodiments can also be understood from the entirety of the specification and the claims filed herein.

Example 1. An apparatus including: a first switch having a first switch terminal coupled to a first terminal and having a second switch terminal; a second switch having a third switch terminal coupled to a second terminal and having a fourth switch terminal; a first amplifier having a first input and a second input; a second amplifier having a third input and having a first output; and a common mode generation circuit having first and second terminals, the first terminal of the common mode generation circuit coupled to the second switch terminal and to the fourth switch terminal, and the second terminal of the common mode generation circuit coupled to the first amplifier and to the third input.

Example 2. The apparatus of example 1, further including: a first electrostatic discharge (ESD) circuit coupled between the first terminal and the second and fourth switch terminals; and a second ESD circuit coupled between the second terminal and the second and fourth switch terminals.

Example 3. The apparatus of one of examples 1 or 2, further including: a third ESD circuit coupled between a third terminal and the second and fourth switch terminals; and a fourth ESD circuit coupled between a fourth terminal and the second and fourth switch terminals.

Example 4. The apparatus of one of examples 1 to 3, where the common mode generation circuit includes a current source circuit coupled to a resistor, where one terminal of the resistor is coupled to the first terminal of the common mode generation circuit and another terminal of the resistor is coupled to the second terminal of the common mode generation circuit.

Example 5. The apparatus of one of examples 1 to 4, further including a third switch coupled between the second terminal of the common mode generation circuit and the first input and including a fourth switch coupled between the second terminal of the common mode generation circuit and the second input.

Example 6. The apparatus of one of examples 1 to 5, further including: a first ground switch circuit coupled between a third terminal and a ground terminal; and a second ground switch circuit coupled between a fourth terminal and the ground terminal.

Example 7. The apparatus of one of examples 1 to 6, where: the first ground switch circuit includes a first transistor coupled in series with a second transistor between the third terminal and the ground terminal, the first ground switch circuit also includes a first buffer coupled to the first and second transistors; and the second ground switch circuit includes a third transistor coupled in series with a fourth transistor between the third terminal and the ground terminal, the second ground switch circuit also includes a second buffer coupled to the third and fourth transistors.

Example 8. The apparatus of one of examples 1 to 7, where the first amplifier has a third output, and the apparatus further includes a third amplifier having a fourth input and a fifth input, the fourth input coupled to the second terminal, and the fifth input coupled to the third output.

Example 9. The apparatus of one of examples 1 to 8, further including a bias resistor circuit having a bias resistor circuit input coupled to the first output, the bias resistor circuit having a first bias circuit output coupled to a third terminal and having a second bias resistor circuit output coupled to a fourth terminal.

Example 10. An integrated circuit (IC) including: an audio amplifier having first and second inputs coupled to respective first and second terminals of the IC; a microphone bias amplifier having a third input and having a first output, the first output coupled to a third or fourth terminal of the IC; and a common mode generation circuit having a second output coupled to the audio amplifier and to the microphone bias amplifier, the common mode generation circuit configured to provide a common mode voltage for the audio amplifier and the microphone bias amplifier, the common mode generation circuit having a first ground coupled to a fifth or sixth terminal of the IC.

Example 11. The IC of example 10, where the audio amplifier is a first audio amplifier, the first audio amplifier having an output, and the IC further includes a second audio amplifier having fourth and fifth inputs, the fourth input coupled to the second output, and the fifth input coupled to the output of the first audio amplifier.

Example 12. The IC of one of examples 10 or 11, where the microphone bias amplifier is configured to provide a voltage that includes a direct current (DC) voltage combined with a signal indicative of audio to the third or fourth terminal of the IC.

Example 13. The IC of one of examples 10 to 12, further including: a first ground switch circuit coupled between the third terminal and a second ground; a second ground switch circuit coupled between the fourth terminal and the second ground; a first circuit coupled to the third and fourth terminals, the first circuit configured to: detect which of the third or fourth terminals is coupled to a third ground; and enable the first or second ground switch circuit coupled to the third or fourth terminal detected as being coupled to the third ground.

Example 14. The IC of one of examples 10 to 13, further including: a first switch coupled between the fifth terminal and the first ground; and a second switch coupled between the sixth terminal and the first ground, where the first circuit is configured to close one of the first or second switches in response to detecting which of the third or fourth terminals is coupled to the third ground.

Example 15. The IC of one of examples 10 to 14, further including: a first switch coupled between the first output and the third terminal; and a second switch coupled between the first output and the third terminal, where the first circuit is configured to close one of the first or second switches in response to detecting which of the third and fourth terminals is coupled to the third ground.

Example 16. The IC of one of examples 10 to 15, where the common mode generation circuit is configured to provide the common mode voltage by flowing current through a resistor.

Example 17. The IC of one of examples 10 to 16, further including an electrostatic discharge circuit coupled between at the first, second, third, fourth, fifth, or sixth terminal and the first ground.

Example 18. A system including: an audio connector; and an audio amplifier having inputs coupled to the audio connector; a microphone bias amplifier having an input and a first output, the first output coupled through to the audio connector; and a common mode generation circuit having a second output coupled to an input of the inputs of the audio amplifier and to the input of the microphone bias amplifier, the common mode generation circuit having a common mode generation circuit ground coupled to the audio connector.

Example 19. The system of example 18, further including: a first switch having a first switch terminal coupled to the audio connector and having a second switch terminal coupled to the common mode generation circuit ground; and a second switch having a third switch terminal coupled to the audio connector and having a fourth switch terminal coupled to the common mode generation circuit ground.

Example 20. The system of one of examples 18 or 19, further including: a first electrostatic discharge (ESD) circuit coupled between the first switch terminal and the common mode generation circuit ground; and a second ESD circuit coupled between the second switch terminal and common mode generation circuit ground.

Example 21. The system of one of examples 18 to 20, where the audio connector includes: a speaker contact; a microphone contact coupled to one input of the audio amplifier; and a ground contact coupled to another input of the audio amplifier.

Example 22. The system of one of examples 18 to 21, further including a printed circuit board (PCB) on which an integrated circuit (IC) is mounted, the IC including the audio amplifier, the microphone bias amplifier, and the common mode generation circuit.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An apparatus comprising:
a first switch having a first switch terminal coupled to a first terminal and having a second switch terminal;
a second switch having a third switch terminal coupled to a second terminal and having a fourth switch terminal;
a first amplifier having a first input and a second input;
a second amplifier having a third input and having a first output; and
a common mode generation circuit having first and second terminals, the first terminal of the common mode generation circuit coupled to the second switch terminal and to the fourth switch terminal, and the second terminal of the common mode generation circuit coupled to the first amplifier and to the third input.

2. The apparatus of claim 1, further comprising:
a first electrostatic discharge (ESD) circuit coupled between the first terminal and the second and fourth switch terminals; and
a second ESD circuit coupled between the second terminal and the second and fourth switch terminals.

3. The apparatus of claim 2, further comprising:
a third ESD circuit coupled between a third terminal and the second and fourth switch terminals; and
a fourth ESD circuit coupled between a fourth terminal and the second and fourth switch terminals.

4. The apparatus of claim 1, wherein the common mode generation circuit includes a current source circuit coupled to a resistor, wherein one terminal of the resistor is coupled to the first terminal of the common mode generation circuit and another terminal of the resistor is coupled to the second terminal of the common mode generation circuit.

5. The apparatus of claim 1, further comprising a third switch coupled between the second terminal of the common mode generation circuit and the first input and comprising a fourth switch coupled between the second terminal of the common mode generation circuit and the second input.

6. The apparatus of claim 1, further comprising:
a first ground switch circuit coupled between a third terminal and a ground terminal; and
a second ground switch circuit coupled between a fourth terminal and the ground terminal.

7. The apparatus of claim 6, wherein:
the first ground switch circuit includes a first transistor coupled in series with a second transistor between the third terminal and the ground terminal, the first ground switch circuit also includes a first buffer coupled to the first and second transistors; and
the second ground switch circuit includes a third transistor coupled in series with a fourth transistor between the third terminal and the ground terminal, the second ground switch circuit also includes a second buffer coupled to the third and fourth transistors.

8. The apparatus of claim 1, wherein the first amplifier has a third output, and the apparatus further comprises a third amplifier having a fourth input and a fifth input, the fourth input coupled to the second terminal, and the fifth input coupled to the third output.

9. The apparatus of claim 1, further comprising a bias resistor circuit having a bias resistor circuit input coupled to the first output, the bias resistor circuit having a first bias circuit output coupled to a third terminal and having a second bias resistor circuit output coupled to a fourth terminal.

10. An integrated circuit (IC) comprising:
an audio amplifier having first and second inputs coupled to respective first and second terminals of the IC;
a microphone bias amplifier having a third input and having a first output, the first output coupled to a third or fourth terminal of the IC; and
a common mode generation circuit having a second output coupled to the audio amplifier and to the microphone bias amplifier, the common mode generation circuit configured to provide a common mode voltage for the audio amplifier and the microphone bias amplifier, the common mode generation circuit having a first ground coupled to a fifth or sixth terminal of the IC.

11. The IC of claim 10, wherein the audio amplifier is a first audio amplifier, the first audio amplifier having an output, and the IC further comprises a second audio amplifier having fourth and fifth inputs, the fourth input coupled to the second output, and the fifth input coupled to the output of the first audio amplifier.

12. The IC of claim 10, wherein the microphone bias amplifier is configured to provide a voltage that includes a direct current (DC) voltage combined with a signal indicative of audio to the third or fourth terminal of the IC.

13. The IC of claim 10, further comprising:
a first ground switch circuit coupled between the third terminal and a second ground;
a second ground switch circuit coupled between the fourth terminal and the second ground;
a first circuit coupled to the third and fourth terminals, the first circuit configured to:
detect which of the third or fourth terminals is coupled to a third ground; and
enable the first or second ground switch circuit coupled to the third or fourth terminal detected as being coupled to the third ground.

14. The IC of claim 13, further comprising:
a first switch coupled between the fifth terminal and the first ground; and
a second switch coupled between the sixth terminal and the first ground, wherein the first circuit is configured to close one of the first or second switches in response to detecting which of the third or fourth terminals is coupled to the third ground.

15. The IC of claim 13, further comprising:
a first switch coupled between the first output and the third terminal; and
a second switch coupled between the first output and the third terminal, wherein the first circuit is configured to close one of the first or second switches in response to detecting which of the third and fourth terminals is coupled to the third ground.

16. The IC of claim 10, wherein the common mode generation circuit is configured to provide the common mode voltage by flowing current through a resistor.

17. The IC of claim 10, further comprising an electrostatic discharge circuit coupled between at the first, second, third, fourth, fifth, or sixth terminal and the first ground.

18. A system comprising:
an audio connector; and
an audio amplifier having inputs coupled to the audio connector;
a microphone bias amplifier having an input and a first output, the first output coupled through to the audio connector; and
a common mode generation circuit having a second output coupled to an input of the inputs of the audio amplifier and to the input of the microphone bias amplifier, the common mode generation circuit having a common mode generation circuit ground coupled to the audio connector.

19. The system of claim 18, further comprising:
a first switch having a first switch terminal coupled to the audio connector and having a second switch terminal coupled to the common mode generation circuit ground; and
a second switch having a third switch terminal coupled to the audio connector and having a fourth switch terminal coupled to the common mode generation circuit ground.

20. The system of claim 19, further comprising:
a first electrostatic discharge (ESD) circuit coupled between the first switch terminal and the common mode generation circuit ground; and
a second ESD circuit coupled between the second switch terminal and common mode generation circuit ground.

21. The system of claim 18, wherein the audio connector includes:
a speaker contact;
a microphone contact coupled to one input of the audio amplifier; and
a ground contact coupled to another input of the audio amplifier.

22. The system of claim 18, further comprising a printed circuit board (PCB) on which an integrated circuit (IC) is mounted, the IC including the audio amplifier, the microphone bias amplifier, and the common mode generation circuit.
